(19) United States
(12) Patent Application Publication
(10) Pub. No.: US 2015/0194290 A1
(43) Pub. Date: Jul. 9, 2015

(54) PLASMA PROCESSING APPARATUS

(71) Applicant: TOKYO ELECTRON LIMITED, Tokyo (JP)

(72) Inventors: Toshihisa Nozawa, Miyagi (JP); Toshihiko Iwao, Miyagi (JP)

(73) Assignee: TOKYO ELECTRON LIMITED, Tokyo (JP)

(21) Appl. No.: 14/416,441

(22) PCT Filed: Apr. 12, 2013
(86) PCT No.: PCT/JP2013/061067

§ 371 Date: Jan. 22, 2015

(30) Foreign Application Priority Data
Jul. 25, 2012 (JP) 2012-164833

(51) Int. Cl. H01J 37/32; C23C 16/511

(52) U.S. Cl. CPC H01J 37/3222; H01J 37/32229; H01J 37/32715; H01J 37/32522; C23C 16/511; H01J 2237/334; H01J 2237/332

(57) ABSTRACT

A plasma processing apparatus according to an exemplary embodiment includes a processing container that defines a processing space; an antenna provided above the processing space and including a disc-shaped wave guiding path around a predetermined axis and a metal plate defining the wave guiding path from a lower side; a microwave generator connected to the antenna and configured to generate microwaves; a stage provided in the processing container and facing the antenna across the processing space to intersect with the predetermined axis; and a heater configured to heat the metal plate. The metal plate includes a plurality of openings along a first circle around the predetermined axis and a second circle having a diameter larger than the first circle. The antenna includes a plurality of protrusions made of a dielectric material extending out into the processing space through the plurality of openings. The microwaves are introduced around the predetermined axis.

### TECHNICAL FIELD

An embodiment of the present invention relates to a plasma processing apparatus.

### BACKGROUND

In a plasma process for manufacturing semiconductor devices, etching or film forming is performed on a processing target substrate by exciting plasma of a processing gas. The plasma may be excited by various methods such as a capacitive coupling method or an inductive coupling method. However, microwaves which can generate low-electron-temperature and high-density plasmas has received attention as a plasma excitation source. A plasma processing apparatus which employs such microwaves as an excitation source is described in Patent Document 1.

The plasma processing apparatus described in Patent Document 1 includes a processing apparatus, a stage, a processing gas supply unit, an antenna, and a microwave generator. The processing container accommodates a stage that places a processing target substrate thereon. The antenna is provided above the stage. This antenna is referred to as a radial line slot antenna, and is connected to the microwave generator through a coaxial waveguide. Further, the antenna includes a cooling jacket, a dielectric plate, a slot plate, and a dielectric window. The dielectric plate has a substantially disc shape, and is sandwiched between the cooling jacket made of a metal and the slot plate in the vertical direction. The slot plate includes a plurality of slot holes formed therein. The slot holes are arranged around the central axis of the coaxial waveguide in the circumferential and radial directions. The substantially disc-shaped dielectric window is provided just below the slot plate. The dielectric window closes an upper opening of the processing container. Further, the supply unit includes a central gas supply unit and an outer gas supply unit. The central gas supply unit supplies a processing gas from the center of the dielectric window. The outer gas supply unit is provided in an annular form between the dielectric window and the stage, and supplies a processing gas at a position lower than the central gas supply unit.

In the plasma processing apparatus described in Patent Document 1, microwaves from the microwave generator are supplied to the antenna through the coaxial waveguide. The microwaves are propagated through the dielectric plate and propagated from the slot holes of the slot plate to the dielectric window. The microwaves, which are propagated through the dielectric window, are then supplied from the dielectric window into the processing container, so that plasma of the processing gases supplied from the supply units is excited.

### PRIOR ART DOCUMENT

### Patent Document

Patent Document 1: International Publication WO2011/125524

### INVENTION OF THE INVENTION

### Problems to be Solved

The microwave plasma generated by the radial line slot antenna of the apparatus described in Patent Document 1 is characterized in that high-energy plasma having a relatively high electron temperature is produced just below the dielectric window (referred to as a plasma excitation region) and diffused therefrom, and becomes plasma having a low electron temperature of about 1 to 2 eV on a processing target substrate placed on the stage. That is, unlike plasma generated by a parallel flat plate, the microwave plasma is characterized by an electron temperature distribution of the plasma clearly defined as a function of distance from the dielectric window. More particularly, the electron temperature of several eV to about 10 eV just below the dielectric window is attenuated to about 1 eV to 2 eV on the processing target substrate. Therefore, since the processing target substrate is processed in a region where the electron temperature of plasma is low (diffusion plasma region), a severe damage such as a recess is not caused to the processing target substrate. Further, in the apparatus described in Patent Document 1, when the processing gas is supplied to a region where the electron temperature of the plasma is high (plasma excitation region), the processing gas is easily excited and dissociated. On the other hand, when the processing gas is supplied to the region where the electron temperature of plasma is low (plasma diffusion region), a degree of dissociation is reduced, as compared with a case where the processing gas is supplied near the plasma excitation region.

However, in the plasma processing apparatus, it is required to reduce non-uniformity of the processing on the entire surface of the processing target substrate. To that end, it is necessary to optimize the density distribution of the plasma generated in the processing container.

In the apparatus described in Patent Document 1, high-density plasma is formed in the region just below the dielectric window, that is, the region where the electron temperature of the plasma is high (plasma excitation region) by supplying the processing gas at a high flow rate from the center of the dielectric window, that is, the central gas supply unit. However, a phenomenon occurs, in which the plasma is significantly localized in the vicinity of the slot. This is because a mean free path of electrons given by the microwaves is short and the electrons collide with gas molecules in the vicinity of the slots, and as a result, the plasma, which is easily excited and dissociated, is localized in the vicinity of the slot. Therefore, in the apparatus described in Patent Document 1, localized plasma generation positions is difficult to control, the plasma density becomes difficult to appropriately control on a wafer plane.

Accordingly, what is requested in the technical field is to improve controllability of plasma generation positions in the plasma processing apparatus in which plasma is excited in the processing container by supplying microwaves from the antenna.

### Means to Solve the Problems

A plasma processing apparatus according to an aspect of the present invention includes a processing apparatus, an antenna, a microwave generator, a stage, and a heater. The processing container defines a processing space. The antenna is provided above the processing space and includes a disc-shaped wave guiding path around a predetermined axis and a metal plate defining the wave guiding path from a lower side. The microwave generator is connected to the antenna and configured to generate microwaves. The stage is provided in the processing container and faces the antenna across the processing space to intersect with the predetermined axis. The heater heats the metal plate. The metal plate includes a plurality of openings along a first circle around the predetermined axis and a second circle having a diameter larger than the first circle around the predetermined axis. The antenna includes a plurality of protrusions made of a dielectric material extending out into the processing space through the plurality of openings. The microwaves are introduced around the predetermined axis.

In the plasma processing apparatus, the microwaves propagated through the plurality of openings of the metal plate from the wave guiding path are concentrated on the plurality of protrusions extending out into the processing container through the plurality of openings. Accordingly, the plasma generation positions are concentrated in the vicinity of the plurality of protrusions. Therefore, the plasma processing apparatus is excellent in controllability of plasma generation positions. Further, the plurality of protrusions is provided along the concentric first and second circles. Accordingly, plasma may be generated at positions dispersed in the circumferential direction and the radial direction with respect to the predetermined axis.

In an exemplary embodiment, the plasma processing apparatus may further include plungers. The plungers are provided with reflection plates that face, among the plurality of protrusions, the protrusions that pass through the openings formed along at least one of the first circle and the second circle through the wave guiding path. The plungers may adjust distances of the reflection plates from the wave guiding path in a direction in which the predetermined axis extends.

According to the exemplary embodiment, a position of the reflection plate of the plunger may be adjusted such that peak positions of stationary waves in the wave guiding path are relatively adjusted with respect to the opening positions of the metal plate. As a result, it is possible to adjust a ratio of a power of the microwaves propagated to the protrusions provided along the first circle and a power of the microwaves propagated to the protrusions provided along the second circles. Hence, it is possible to adjust a plasma density distribution in the radial direction with respect to the predetermined axis.

In an exemplary embodiment, the metal plate includes a plurality of gas injection ports to supply a processing gas to the processing space. According to the exemplary embodiment, the processing gas may be supplied from the upper side of the stage.

In an exemplary embodiment, the plurality of gas injection ports may be formed along at least two concentric circles around the predetermined axis. According to the exemplary embodiment, a flow rate distribution of the processing gas in the radial direction with respect to the predetermined axis may be adjusted.

In an exemplary embodiment, the plasma processing apparatus may further include a cooling jacket provided on the wave guiding path and a heater that heats the metal plate. According to the exemplary embodiment, the antenna may be cooled by the cooling jacket such that components made of a dielectric material in the antenna are suppressed from being destructed by a thermal stress. Further, the metal plate may be heated by the heater such that ions and radicals generated in the processing container, and processing byproducts are suppressed from re-adhering onto the metal plate.

In an exemplary embodiment, the plurality of protrusions may be made of a rod-like dielectric material extending in a direction in which the predetermined axis extends, and the plurality of protrusions may be arranged axisymmetrically with respect to the predetermined axis in the first circle and the second circle. Further, in another exemplary embodiment, the plurality of protrusions may have an arc shape in a cross-section orthogonal to the predetermined axis, and the plurality of protrusions may be arranged axisymmetrically with respect to the predetermined axis in the first circle and the second circle. According to the exemplary embodiments, the plasma distribution in the circumferential direction with respect to the predetermined axis may be uniformized.

### Effect of the Invention

As described above, according to various aspects and embodiments of the present invention, a plasma processing apparatus is provided which is improved in controllability of generation positions of plasma excited in the processing container by supplying microwaves from the antenna.

### BRIEF DESCRIPTION OF THE DRAWINGS

FIG. 1 is a schematic cross-sectional view illustrating a plasma processing apparatus according to an exemplary embodiment.

FIG. 2 is a plan view illustrating an antenna illustrated in FIG. 1 when viewed from the bottom.

FIG. 3 is a cross-sectional view illustrating a metal plate and a plurality of protrusions of the antenna illustrated in FIG. 1 in an enlarged scale.

FIG. 4 is a plan view illustrating an antenna according to another exemplary embodiment when viewed from the bottom.

FIG. 5 is a cross-sectional view illustrating a metal plate and a plurality of protrusions of the antenna according to another exemplary embodiment in an enlarged scale.

FIG. 6 is a perspective view of a configuration of a plasma processing apparatus used in Test Examples.

FIG. 7 is a view illustrating images of light emitting states of plasma in Test Example 1.

FIG. 8 is a view illustrating images of light emitting states of plasma in Test Example 2.

FIG. 9 is a view illustrating electric field intensity ratios of the plasma processing apparatus illustrated in FIG. 6, which is obtained by a simulation.

### DETAILED DESCRIPTION TO EXECUTE THE INVENTION

Hereinafter, various embodiments of the present invention will be described in detail with reference to the accompanying drawings. Further, the same reference numerals will be given to the same or corresponding portions in respective drawings.

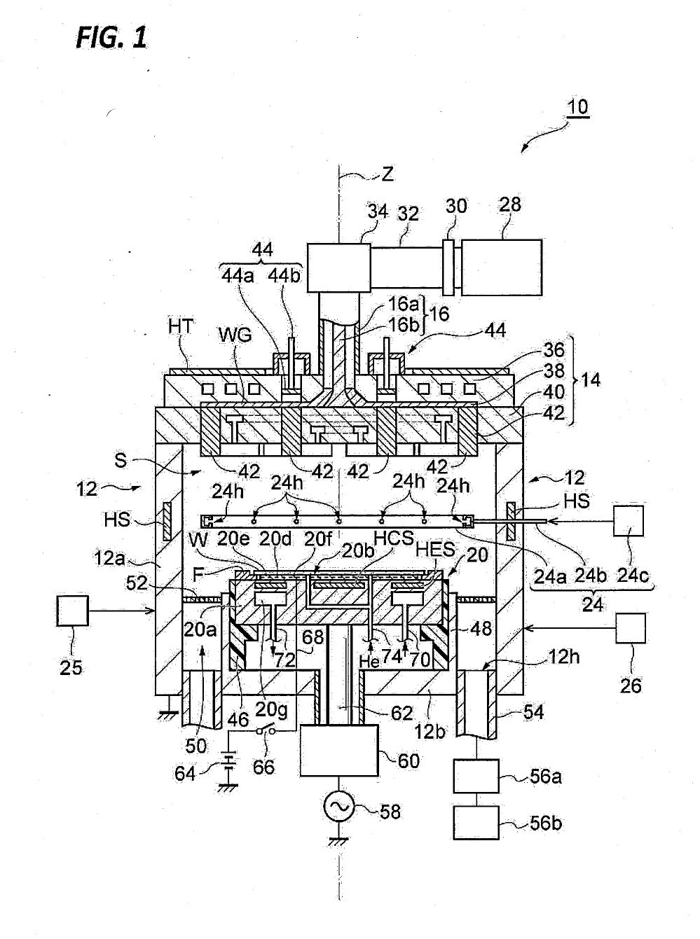

FIG. 1 is a schematic cross-sectional view illustrating a plasma processing apparatus according to an exemplary embodiment. A plasma processing apparatus 10 illustrated in FIG. 1 includes a processing container 12 and an antenna 14. The processing container 12 defines a processing space S to accommodate a processing target substrate W. The processing apparatus 12 may include a sidewall 12a and a bottom 12b. The sidewall 12a has a substantially cylindrical shape that extends in a direction in which a predetermined axis Z (hereinafter, referred to as an “axis Z direction”) extends. The bottom 12b is provided at the lower end of the sidewall 12a. An exhaust hole 12h for exhaust is formed in the bottom 12h. The upper end portion of the sidewall 12a is opened. An opening in the upper end portion of the processing apparatus 12 is closed by the antenna 14.

The plasma processing apparatus 10 further includes a stage 20 provided in the processing container 12. The stage 20 is provided below the antenna 14 and faces the antenna 14 across the processing space S so as to intersect with the axis Z. The processing target substrate W may be placed on the stage 20 such that the center of the processing target substrate W substantially coincides with the axis Z. In an exemplary embodiment, the stage 20 includes a table 20a and an electrostatic chuck 20b.

The table 20a is supported by a cylindrical support 46. The cylindrical support 46 is made of an insulating material and extends vertically upward from the bottom 12b. Further, a conductive cylindrical support 48 is provided on the outer periphery of the cylindrical support 46. The cylindrical support 48 extends vertically upward from the bottom 12b of the processing container 12 along the outer periphery of the cylindrical support 46. An annular exhaust path 50 is formed between the cylindrical support 48 and the sidewall 12a.

An annular baffle plate 52 having a plurality of through-holes is attached to the upper portion of the exhaust path 50. The exhaust path 50 is connected to an exhaust pipe 54 that provides the exhaust hole 12h, and the exhaust pipe 54 is connected with an exhaust device 56b through a pressure regulator 56a. The exhaust device 56b includes a vacuum pump such as a turbo molecular pump. The pressure regulator 56a adjusts exhaust amount of the exhaust device 56b to adjust pressure in the processing container 12. By the pressure regulator 56a and the exhaust device 56b, the processing space S in the processing container 12 may be decompressed to a desired degree of vacuum. Further, the exhaust device 56b may be operated to exhaust the processing gas from the outer periphery of the stage 20 through the exhaust path 50.

The table 20a also serves as a high frequency electrode. The table 20a is electrically connected with a high frequency power supply 58 for RF bias through a matching unit 60 and a power feeding rod 62. The high frequency power supply 58 outputs high frequency power having a constant frequency suitable for controlling energy of ions drawn into the processing target substrate W, for example, 13.56 MHz at a predetermined power. The matching unit 60 accommodates a matcher configured to perform matching between an impedance of the high frequency power supply 58 side and an impedance of a load side such as the electrode, plasma, or the processing container 12. The matcher includes a blocking condenser for self-bias generation.

The electrostatic chuck 20b is provided on the top surface of the table 20a. In an exemplary embodiment, the top surface of the electrostatic chuck 20b is configured as a placing region to place the processing target substrate W thereon. The electrostatic chuck 20b holds the processing target substrate W with an electrostatic attraction force. A focus ring F is provided radially outside of the electrostatic chuck 20b to annularly surround the periphery of the processing target substrate W. The electrostatic chuck 20b includes an electrode 20d, an insulating film 20e, and an insulating film 20f. The electrode 20d is made of a conductive film and provided between the insulating film 20e and the insulating film 20f. The electrode' 20d is connected with a high voltage DC power supply 64 through a switch 66 and a coated wire 68. The electrostatic chuck 20b may attract and hold the processing target substrate W on its top surface with Coulomb force generated by DC voltage applied from the DC power supply 64.

An annular coolant chamber 20g is provided inside the table 20a to extend in the circumferential direction. A coolant with a predetermined temperature such as, for example, cooling water, is circulated and supplied from a chiller unit through pipes 70, 72 to the coolant chamber 20g. The processing temperature of the processing target substrate W on the electrostatic chuck 20b may be controlled by the temperature of the coolant. Further, a heat transfer gas from a heat transfer gas supplying unit such as, for example, helium (He) gas, is supplied to a gap between the top surface of the electrostatic chuck 20b and the rear surface of the processing target substrate W through a gas supply pipe 74.

In an exemplary embodiment, the plasma processing apparatus 10 may further include heaters HS, HCS, and HES as temperature control mechanisms. The heater HS is provided inside the sidewall 12a to extend in an annular form. The heater HS may be provided, for example, at a position corresponding to a middle of the height direction (that is, the axis Z direction) of the processing space S. The heater HCS is provided inside the table 20a. Inside the table 20a, the heater HCS is provided below the central portion of the above-mentioned placing region, that is, in a region intersecting with the axis Z. Further, the heater HES is provided inside the table 20a and extends annularly to surround the heater HCS. The heater HES is provided below the outer peripheral portion of the above-mentioned placing region.

The plasma processing apparatus 10 further includes a gas supplying unit 24. The gas supplying unit 24 includes an annular pipe 24a, a pipe 24b, and a gas source 24c. The annular pipe 24a is provided inside the processing container 12 to extend in an annular form around the axis Z at a middle position of the axis Z direction of the processing space S. The annular pipe 24a includes a plurality of gas injection ports 24h that are opened toward the axis Z. The plurality of gas injection ports 24h is arranged annularly around the axis Z. The annular pipe 24a is connected with the pipe 24b. The pipe 24b extends to the outside of the processing container 12 and connected to the gas source 24c. The gas source 24c is a gas source of the processing gas, and supplies the processing gas to the pipe 24b while controlling the flow rate of the processing gas. The gas source 24c may include, for example, an opening/closing valve and a mass flow controller.

The gas supplying unit 24 introduces the processing gas into the processing space S toward the axis Z though the pipe 24b, the annular pipe 24a, and the gas injection ports 24h. The processing gas is properly selected depending on the processing performed on the processing target substrate W in the plasma processing apparatus 10. For example, in a case where etching is performed on the processing target substrate W, the processing gas may include an etchant gas and/or an inert gas. Further, in a case where a film formation is performed on the processing target substrate W, the processing gas may include a raw material gas and/or an inert gas.

As illustrated in FIG. 1, the plasma processing apparatus 10 further includes a coaxial waveguide 16, a microwave generator 28, a tuner 30, a waveguide 32, and a mode converter 34, in addition to the antenna 14. The microwave generator 28 generates microwaves having a frequency of, for example, 2.45 GHz. The microwave generator 28 is connected to the upper portion of the coaxial waveguide 16 through the tuner 30, the waveguide 32, and the mode converter 34.

The coaxial waveguide 16 extends along the axis Z which is the central axis thereof. The coaxial waveguide 16 includes an outer conductor 16a and an inner conductor 16b. The outer conductor 16a has a cylindrical shape which extends in the axis Z direction. The lower end of the outer conductor 16a may be electrically connected to the upper portion of a cooling jacket 36 which has a conductive surface. The inner conductor 16b is provided inside the outer conductor 16a. The inner conductor 16b has a substantially cylindrical shape which extends along the axis Z. The lower end of the inner conductor 16b is connected to a metal plate 40 of the antenna 14.

In an exemplary embodiment, the antenna 14 may be provided in an upper end opening of the processing container 12. The antenna 14 defines a substantially disc-shaped wave guiding path WG around the axis Z. In an exemplary embodiment, the antenna 14 may include the cooling jacket 36, a dielectric plate 38, a metal plate 40, and a plurality of protrusions 42. The cooling jacket 36 is provided on the wave guiding path WG. In an exemplary embodiment, the bottom surface of the cooling, jacket 36 which is made of a metal, defines the wave guiding path WG from the top. The metal plate 40 is a substantially disc-shaped member made of a metal, and defines the wave guiding path WG from the bottom. The dielectric plate 38 is sandwiched between the cooling jacket 36 and the metal plate 40. The dielectric plate 38 shortens the wavelength of the microwaves. The dielectric plate 38 is made of, for example, quartz or alumina, and has a substantially disc shape. The dielectric plate 38 constitutes the wave guiding path WG between the cooling jacket 36 and the metal plate 40.

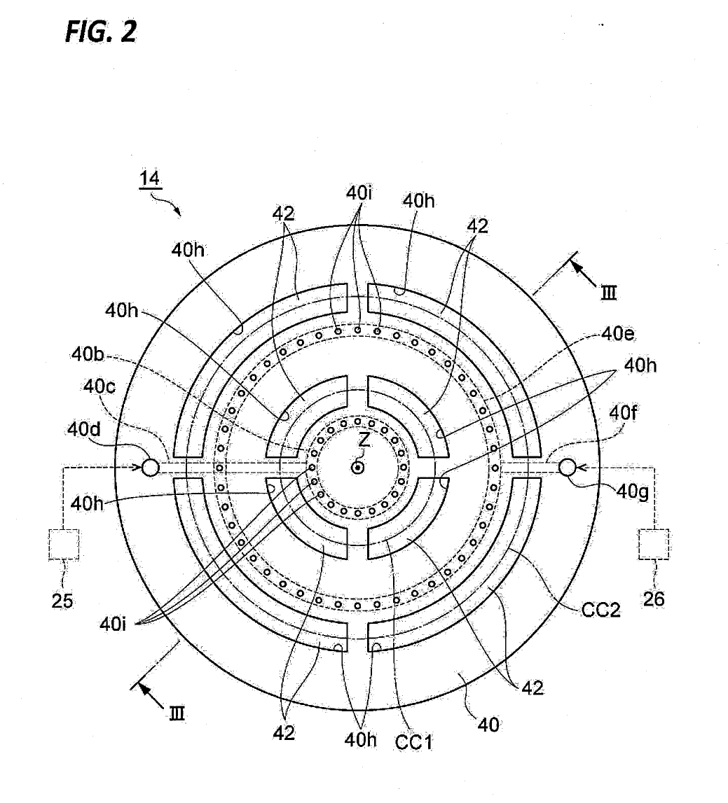

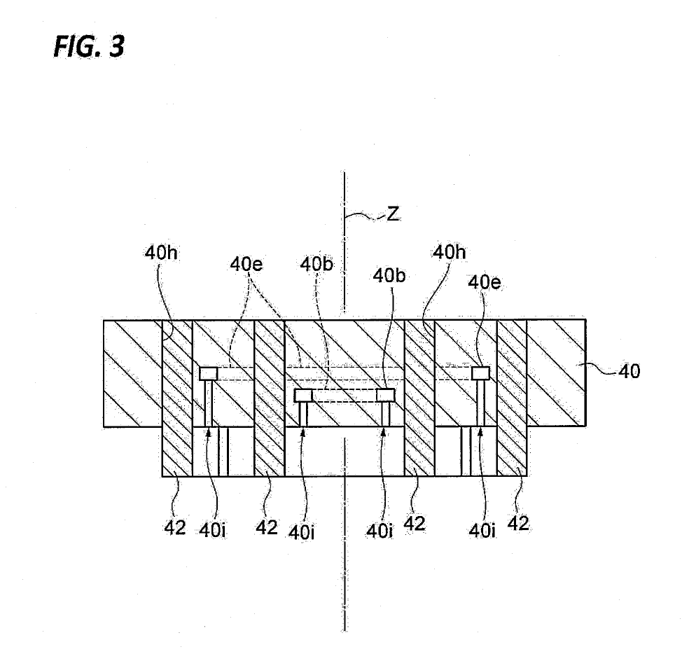

Hereinafter, FIGS. 2 and 3 will be referenced together with FIG. 1. FIG. 2 is a plan view illustrating an antenna illustrated in FIG. 1 when viewed from the bottom. FIG. 3 is a cross-sectional view illustrating a metal plate and a plurality of protrusions of the antenna illustrated in FIG. 1 in an enlarged scale. Further, FIGS. 1 and 3 illustrate a cross-section of the metal plate 40 taken along line in FIG. 2. As illustrated in FIGS. 1 to 3, the metal plate 40 includes a plurality of openings 40h that penetrates the metal plate 40 in the axis Z direction.

Some of the openings 40h (four openings 40h in FIG. 2) extend along a first circle CC1 around the axis Z. That is, the plurality of openings 40h along the first circle CC1 has an arc and strip shape as a planar shape in a plane orthogonal to the axis Z. The remaining openings 40h (other four openings 40h in FIG. 2) extend along a second circle CC2 having a diameter larger than that of the first circle CC1 around the axis Z. That is, each of the openings 40h along the second circle CC2 has an arc and strip shape as a planar shape in a plane orthogonal to the axis Z. In an exemplary embodiment, the plurality of openings 40h is formed axisymmetrically with respect to the axis Z.

Further, the antenna 14 further includes the plurality of protrusions 42 that extends out into the processing space S through the plurality of openings 40h. In an exemplary embodiment, the protrusions 42 are in contact with the dielectric plate 38 at the upper ends thereof and extend below the bottom surface of the metal plate 40.

Further, each of the protrusions 42 has a planar shape similar in a cross-section in the plane orthogonal to the axis Z to the corresponding opening among the plurality of openings 40h. That is, each of the protrusions 42 passing through the openings 40h formed along the first circle CC1 has an arc and strip cross-sectional shape similar to the planar shape of the corresponding opening formed along the first circle CC1. In addition, each of the protrusions 42 passing through the openings 40h formed along the second circle CC2 has an arc and strip cross-sectional shape similar to the planar shape of the corresponding openings formed along the second circle CC2. The plurality of protrusions 42 is made of a dielectric material such as, for example, quartz. Further, a film made of Y₂O₃ or quartz may be formed on the bottom surface of the metal plate 40, particularly, in a region of the metal plate 40 that faces the processing space S.

In the plasma processing apparatus 10 including the antenna 14 as configured above, the microwaves generated by the microwave generator 28 are propagated to the wave guiding path WG, that is, the dielectric plate 38 via the tuner 30, the waveguide 32, the mode convertor 34, and the concentric waveguide 16. The microwaves propagated to the dielectric plate 38 become stationary waves. Then, the microwaves leak out to the plurality of protrusions 42 passing though the plurality of openings 40h of the metal plate 40, and are supplied to the processing space S. Therefore, in the plasma processing apparatus 10, the microwaves leaking out of the metal plate 40 are concentrated on the plurality of protrusions 42 rather than the entire region below the metal plate 40. As a result, the plasma generation positions of the processing gas are concentrated in the vicinity of the plurality of protrusions 42. Accordingly, the plasma processing apparatus 10 is excellent in controllability of the plasma generation positions.

Further, the plurality of protrusions 42 are provided along the concentric first and second circles, as well as axisymmetrically with respect to the axis Z. Accordingly, in the plasma processing apparatus 10, the plasma generation positions may be distributed in the radial direction with respect to the axis Z, as well as in the circumferential direction with respect to the axis Z. As a result, according to the plasma processing apparatus 10, the plasma density distribution may be uniformized in the circumferential direction and the radial direction with respect to the axis Z. Further, according to the plasma processing apparatus 10, it is possible to handle the plasma localization just below the antenna 14, which may occur when a large amount of the processing gas is supplied just below the antenna 14, as well as to realize a more optimal plasma density control even when the processing gas is supplied at a medium or low flow rate.

In an exemplary embodiment, as illustrated in FIG. 1, the plasma processing apparatus 10 may further include a plurality of plungers 44. Each of the plurality of plungers 44 includes a reflection plate 44a and a positioning mechanism 44b. In the exemplary embodiment illustrated in FIG. 1, the reflection plates 44a of the plurality of plungers 44 are provided to face the plurality of protrusions 42 provided along the first circle CC1, across the wave guiding path WG.

Further, as illustrated in FIG. 1, the reflection plate 44a of each plunger 44 is connected to the positioning mechanism 44b configured to adjust a position in the axis Z direction. In the plasma processing apparatus 10, the position of the reflection plate 44a may be adjusted using the positioning mechanism 44b such that the peak positions of the stationary waves in the wave guiding path WG are adjusted. As a result, it is possible to adjust a ratio of a power of the microwaves leaking out to the protrusions 42 provided along the first circle CC1 and a power of the microwaves leaking out to the protrusions 42 provided along the second circle CC2. Accordingly, the plasma density distribution may be adjusted in the radial direction with respect to the axis Z.

In another exemplary embodiment, the plurality of plungers 44 may be provided such that the reflection plates 44a face the plurality of protrusions 42 provided along the second circle CC2, or such that all the protrusions 42 and the reflection plates 44a face each other.

FIGS. 1 to 3 will be referenced again. In an exemplary embodiment, the metal plate 40 includes a plurality of gas injection ports 40i to supply the processing gas to the processing space S. The gas injection ports 40i are opened downwardly. In the example illustrated in FIGS. 1 to 3, the plurality of gas injection ports 40i are arranged along two concentric circles around the axis Z. Further, the metal plate 40 includes an annular gas line 40b that is connected to the gas injection ports 40i arranged along the inner circle among the two concentric circles. The gas line 40b is connected with a gas line 40c that extends toward the periphery of the metal plate 40. The gas line 40c is connected to a port 40d that is provided on the bottom surface of the metal plate 40. The port 40d is connected to a gas source 25 through a gas line provided inside the sidewall 12a of the processing container 12. Similarly to the gas source 24c, the gas source 25 is a gas source of a processing gas, and is configured to control the flow rate of the processing gas.

Further, the metal plate 40 includes an annular gas line 40e that is connected to the gas injection ports 40i arranged along the outer circle among the two concentric circles. The gas line 40e is connected with a gas line 40f that extends toward the periphery of the metal plate 40. The gas line 40f is connected to a port 40g that is provided on the bottom surface of the metal plate 40. The port 40g is connected to a gas source 26 through a gas line provided inside the sidewall 12a of the processing container 12. Similarly to the gas source 24c, the gas source 26 is a gas source of a processing gas, and is configured to control the flow rate of the processing gas.

The plasma processing apparatus 10 includes the plurality of gas injection ports 40i configured to supply the processing gas downwardly from the top of the processing space S, in addition to the plurality of gas injection ports 24h arranged annularly at the middle positon of the height direction of the processing space S. Further, the gas injection ports 40i are arranged along two concentric circles. Accordingly, in the plasma processing apparatus 10, the processing gas may be supplied from the upper side of the processing space S toward the processing target substrate W. Further, a flow rate distribution of the processing gas in the radial direction with respect to the axis Z may be adjusted. In another exemplary embodiment, the plurality of gas injection ports 40i may be arranged along three or more concentric circles.

FIG. 1 will be referenced again. In the plasma processing apparatus 10, a heater HT is provided on the cooling jacket 36. The heater HT heats the metal plate 40 through the cooling jacket 36. Therefore, ions and radicals generated in the processing container 12, and processing byproducts may be suppressed from re-adhering onto the metal plate 40. In addition, in the plasma processing apparatus 10, the antenna 14 may be cooled by the cooling jacket 36. Accordingly, the dielectric plate 38 or the protrusions 42 made of a dielectric material may be suppressed from being destroyed by thermal stress.

The plasma processing apparatus 10 according to an exemplary embodiment has been described in detail. As described above, the plasma processing apparatus 10 has an effect that controllability of plasma generation positions is excellent. However, the effect may be effectively exhibited especially in a case where the pressure in the processing container 12 is a high pressure, for example, 1 Torr (133.3 Pa) or more. Hereinafter, the reasons will be described.

As illustrated in the following Equation (1), behaviors of flows of electrons and ions constituting plasma in the processing container 12 may be represented by the following transport equation.

Γ=Γₑ=Γᵢ=−D∇n (1)

Here, the plasma is assumed as plasma that does not contain negative ions. In Equation (1), Γ, Γₑ, and Γᵢ represent fluxes of plasma, electrons, and ions, respectively, D represents a bipolar diffusion coefficient, and n represents a plasma density. Further, the bipolar diffusion coefficient D may be represented by the following Equation (2).

$$\begin{matrix}[ Equation 2 ] & \\ D = \frac{{μ}_{i} {D}_{e} + {μ}_{e} {D}_{i}}{{μ}_{i} + {μ}_{e}} & ( 2 )\end{matrix}$$

In Equation (2), μₑ and μᵢ represent mobilities of electrons and ions, respectively, and Dₑ and Dᵢ represent diffusion coefficients of electrons and ions, respectively. The mobility and diffusion coefficient of a particle species s are represented by the following Equation (3) and Equation (4), respectively.

$$\begin{matrix}[ Equation 3 ] & \\ {μ}_{s} = \frac{\vert {q}_{s} \vert}{{m}_{s} {v}_{sm}} & ( 3 ) \\ [ Equation 4 ] & \\ {D}_{s} = \frac{{k}_{B} {T}_{s}}{{m}_{s} {v}_{sm}} & ( 4 )\end{matrix}$$

In Equations (3) and (4), qₛ represents an electric charge amount of the particle species s, k_{B} represents a Boltzmann constant, Tₛ represents a temperature of the particle species s, mₛ represents a mass of the particle species s, and νₛₘ represents a collision frequency between the particle species s and a neural particle. When Equations (3) and (4) are substituted into Equation (2) assuming that all the ions are monovalent cations, Equation (5) is obtained.

$$\begin{matrix}[ Equation 5 ] & \\ D = {k}_{B} \frac{{T}_{i} + {T}_{e}}{{m}_{e} {v}_{em} + {m}_{i} {v}_{im}} & ( 5 )\end{matrix}$$

Here, when the microwaves having the same power, are input in both cases where the pressure in the processing container 12 is high and where the pressure in the processing container 12 is low, so that the amount of electrons generated and the amount of ions generated are equal to each other, macroscopic fluxes Γ of plasma for both cases are maintained to be identical with each other. Further, when the pressure in the processing container 12 becomes high, the collision frequency νₛₘ between the particle species s and the neutral particle increases, and from Equation (5), when the pressure in the processing container 12 becomes high, the bipolar diffusion coefficient D becomes smaller than a diffusion coefficient for a case where the pressure in the processing container 12 is low. Accordingly, in the relationship of Equation (1), in order to make the flux Γ of the plasma in the case where the pressure in the processing container 12 is high equal to the flux Γ of the plasma in the case where the pressure in the processing container 12 is low, a strong plasma density gradient is needed. Further, a frequency of electrons to cause inelastic collisions such as, for example, excitation collisions or ionization collisions increases, and thus, a moving distance until the electrons loses energy due to the inelastic collisions after generation is shortened. Therefore, when the pressure in the processing container 12 becomes high, a plasma localization phenomenon may occur even when it is intended to diffuse the plasma in a wide region. Further, when the microwaves generate plasma in the processing container through a planar dielectric plate having a wide area, a plasma generation positions are determined by a stationary wave mode within the dielectric plate. Accordingly, even though a microwave input position is specified on, for example, a slot plate, it is difficult to sufficiently obtain controllability of the plasma generation positions.

Meanwhile, in the plasma processing apparatus 10, since the microwaves are concentrated on the plurality of protrusions 42 which are restricted in the area to be in contact with the processing space S, the plasma generation positions may be controlled to be located in the vicinity of the protrusions 42 even under a high pressure. Accordingly, the plasma processing apparatus 10 is excellent in controllability of the plasma generation positions even under a high pressure.

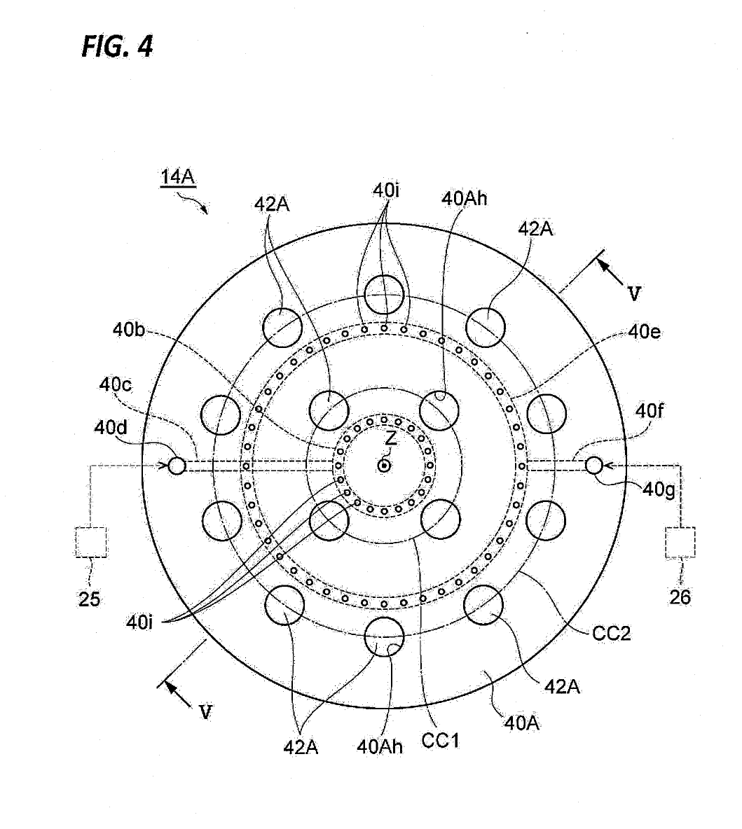

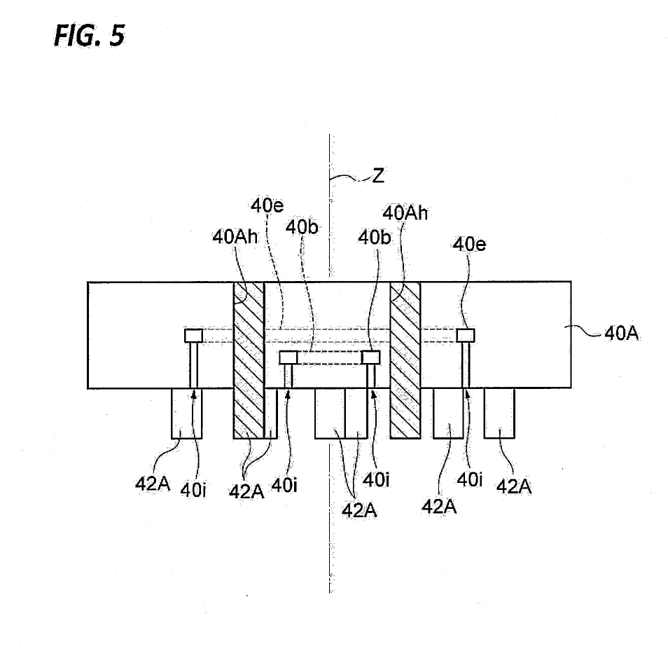

Hereinafter, an antenna according to another exemplary embodiment will be described with reference to FIGS. 4 and 5. FIG. 4 is a plan view illustrating an antenna according to another exemplary embodiment when viewed from the bottom. FIG. 5 is a cross-sectional view illustrating a metal plate and a plurality of protrusions of the antenna according to another exemplary embodiment in an enlarged scale, and illustrates a cross-section taken along line V-V in FIG. 4. A metal plate 40A of an antenna 14A illustrated in FIG. 4 includes a plurality of openings 40Ah. The plurality of openings 40Ah is arranged along concentric circles CC1 and CC2, and formed axisymmetrically with respect to an axis Z. Unlike the openings 40h of the metal plate 40, each of openings 40Ah has a circular shape as a planar shape in a plane orthogonal to the axis Z.

Further, the antenna 14A is provided with a plurality of rod-like protrusions, that is, cylindrical protrusions 42A passing through the plurality of openings 40Ah. The protrusions 42A are in contact with the dielectric plate 38 at its upper end and extend below the bottom surface of the metal plate 40A. The antenna 14A having such a configuration is provided with a plurality of cylindrical protrusions 42A, but has the same effect as the effect exhibited by the antenna 14. Accordingly, the plurality of protrusions may have any shape as long as they extend out from the openings formed on the metal plate of the antenna to a bottom side of the metal plate so as to be in contact with the processing space S in a limited area.

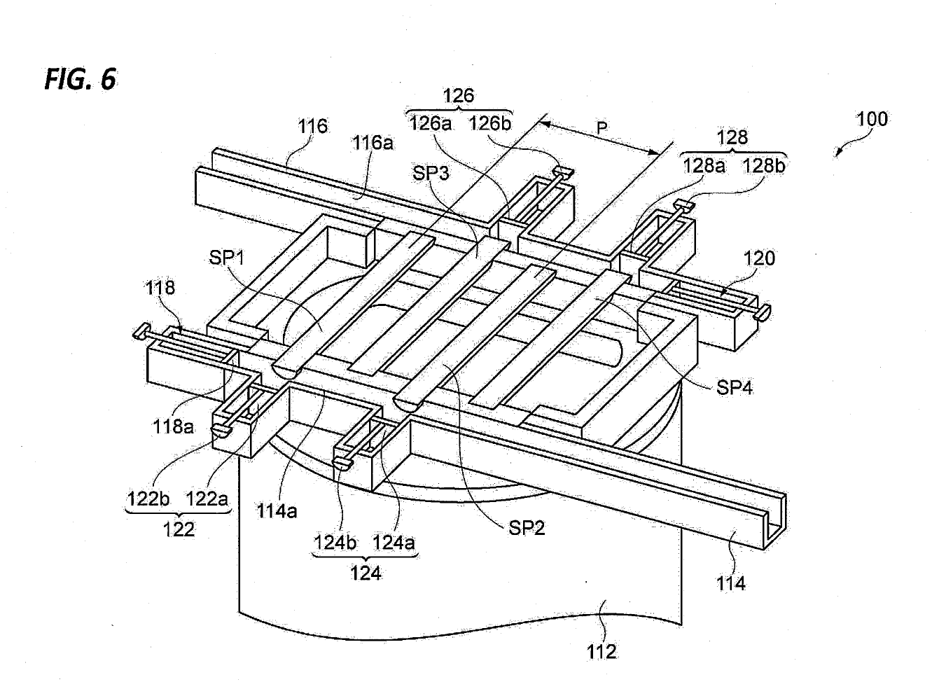

Hereinafter, descriptions will be made on Test Examples 1 and 2 and a simulation in which it is verified that plasma generation positions may be controlled by concentrating microwaves on the dielectric in contact with a processing space S in a limited area. FIG. 6 is a perspective view of a configuration of a plasma processing apparatus used in Test Examples.

A plasma processing apparatus 100 illustrated in FIG. 6 includes four rods SP1 to SP4 made of a dielectric material above a processing container 112. The rods SP1 to SP4 each have a diameter of 40 mm and a length of 353 mm, and are arranged in parallel with each other at 100 mm intervals. Further, as illustrated in FIG. 6, the rods are arranged in a direction where the rods SP1, SP3, SP2, and SP4 are disposed in this order.

Further, the plasma processing apparatus 100 includes two rectangular waveguides 114 and 116. A cross-sectional size of each of the rectangular waveguides 114 and 116 is 109.2 mm×54.6 mm pursuant to EIA standard WR-430. The waveguides 114 and 116 extend in a direction orthogonal to the extending direction of the rods SP1 to SP4 and are provided such that the rods SP1 to SP4 are interposed between the waveguides 114 and 116. The waveguide 114 includes a plunger 118 in the reflecting end thereof, and the waveguide 116 includes a plunger 120 in the reflecting end thereof. One end of each of the rods SP1 and SP2 is positioned within the wave guiding path of the waveguide 114, and the other end of each of the rods SP1 and SP2 is terminated in front of the wave guiding path of the waveguide 116. Specifically, one end of each of the rods SP1 and SP2 is introduced into the waveguide 114 by a length of 30 mm. Further, one end of each of the rods SP3 and SP4 is positioned within the wave guiding path of the waveguide 116, and the other end of each of the rods SP3 and SP4 is terminated in front of the wave guiding path of the waveguide 114. Specifically, one end of each of the rods SP3 and SP4 is introduced into the waveguide 116 by a length of 30 mm.

Plungers 122 and 124 are attached to the waveguide 114. The plunger 122 includes a reflection plate 122a and a positioning mechanism 122b. The reflection plate 122a faces one end of the rod SP1 through the wave guiding path of the waveguide 114. The positioning mechanism 122b has a function of adjusting a position of the reflection plate 122a from one surface (denoted by a reference numeral 114a) of the waveguide 114 which defines the wave guiding path. Further, the plunger 124 includes a reflection plate 124a and a positioning mechanism 124b. The reflection plate 124a faces one end of the rod SP2 through the wave guiding path of the waveguide 114. The positioning mechanism 124b is capable of adjusting a position of the reflection plate 124a from one surface 114a of the waveguide 114.

Further, plungers 126 and 128 are attached to the waveguide 116. The plunger 126 includes a reflection plate 126a and a positioning mechanism 126b. The reflection plate 126a faces one end of the rod SP3 through the wave guiding path of the waveguide 116. The positioning mechanism 126b has a function of adjusting a position of the reflection plate 126a from one surface (denoted by a reference numeral 116a) of the waveguide 116 which defines the wave guiding path. Further, the plunger 128 includes a reflection plate 128a and a positioning mechanism 128b. The reflection plate 128a faces one end of the rod SP4 through the wave guiding path of the waveguide 116. The positioning mechanism 128b is capable of adjusting a position of the reflection plate 128a from one surface 116a of the waveguide 116 which defines the wave guiding path.

In Test Examples 1 and 2, Ar gas was supplied into the processing container 112 of the plasma processing apparatus 100 having the above-mentioned configuration, and the microwaves having a frequency of 2.45 GHz were supplied into the processing container 112 with 1 kW microwave power. Further, in Test Examples 1 and 2, a distance d1 between the reflection plate 122a and one surface of the waveguide 114 and a distance d2 between the reflection plate 124a and one surface of the waveguide 114 were set as parameters and varied. Further, in Test Examples 1 and 2, the distance between the rod SP1 and the rod SP2 was set to 200 mm. Further, in Test Example 1, the pressure in the processing container 112 was set to 100 mTorr (13.33 Pa), and in Test Example 2, the pressure in the processing container 112 was set to 1 Torr (133.3 Pa). Further, the distance between the reflection plate 118a of the plunger 118 and the axis of the rod SP1 was set to 85 mm.

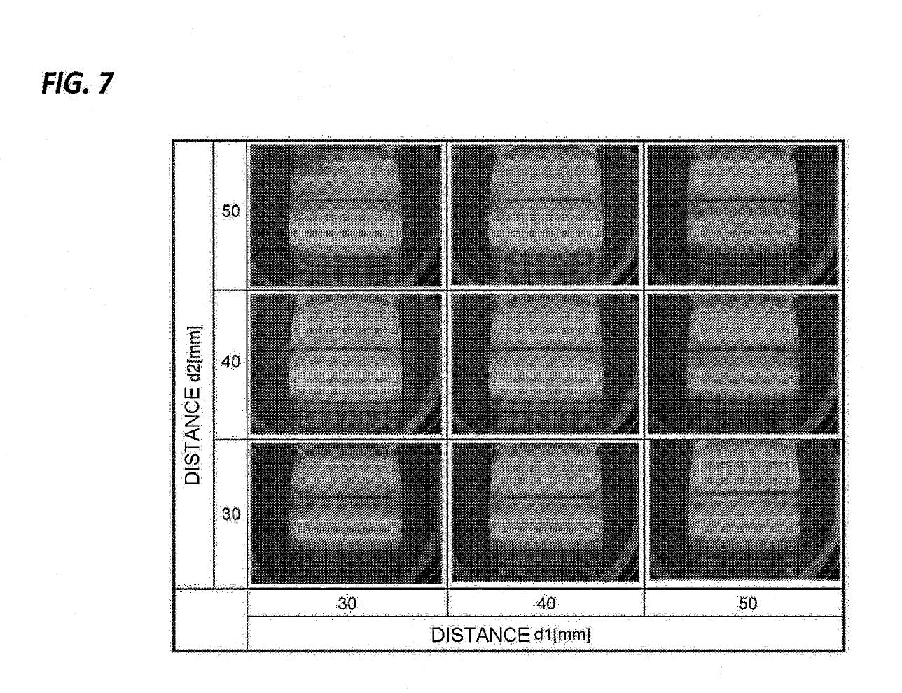

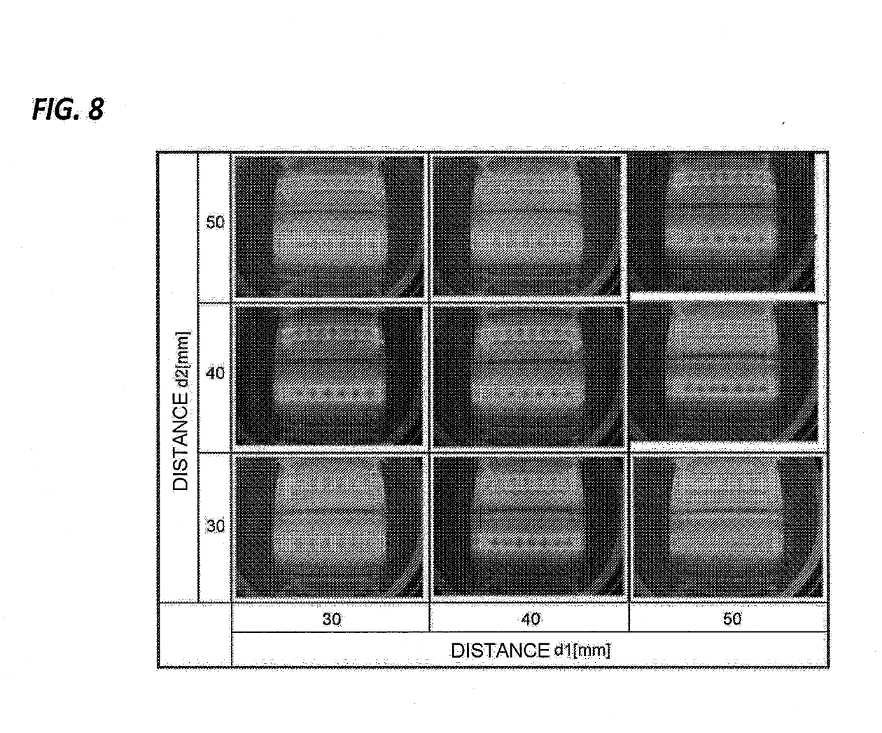

Also, in both Test Example 1 and Test Example 2, a light emitting state of plasma was photographed from the underside of the rods SP1 and SP2. FIG. 7 is a view illustrating images of light emitting states of plasma in Test Example 1. FIG. 8 is a view illustrating images of light emitting states of plasma in Test Example 2. FIGS. 7 and 8 illustrate images obtained by corresponding with the setting values of the distance d1 and the distance d2 and photographing the light emitting states of plasma under the setting values of the distance d1 and the distance d2 in a matrix form.

In the images illustrated in FIGS. 7 and 8, a portion with a relatively high brightness indicates light emission of plasma in the vicinity of the rods SP1 and SP2. Accordingly, from results of Experiment 1 and Experiment 2, it has been found that the plasma generation positions may be controlled to be located in the vicinity of the rods SP1 and SP2. From this, it has been found that the plasma generation positions may be concentrated on the vicinity of a member made of a dielectric material extending from the wave guiding path due to a configuration in which the member is in contact with the processing space in the processing container in a limited area.

Further, as illustrated in FIGS. 7 and 8, it has been found that the distances d1 and d2, that is, the distance between the reflection plate 122a and the wave guiding path of the waveguide 114 and the distance between the reflection plate 124a and the wave guiding path of the waveguide 114 may be adjusted such that a ratio of brightness of plasma located in the vicinity of the rod SP1 and brightness of plasma located in the vicinity of the rod SP2 are relatively varied. Accordingly, from the results of Test Examples 1 and 2, it has been found that the distances d1 and d2 may be adjusted such that a ratio of plasma density in the vicinity of the rod SP1 and plasma density in the vicinity of the rod SP2 is adjusted. From this, it has been found that, in the configuration in which the plurality of members made of a dielectric material extending from the wave guiding path are in contact with the processing space in the processing container in a restricted area, the distances of the reflection plates of the plungers from the wave guiding paths may be adjusted such that the density distribution of plasma concentrated in the vicinity of the members made of a dielectric material is adjusted.

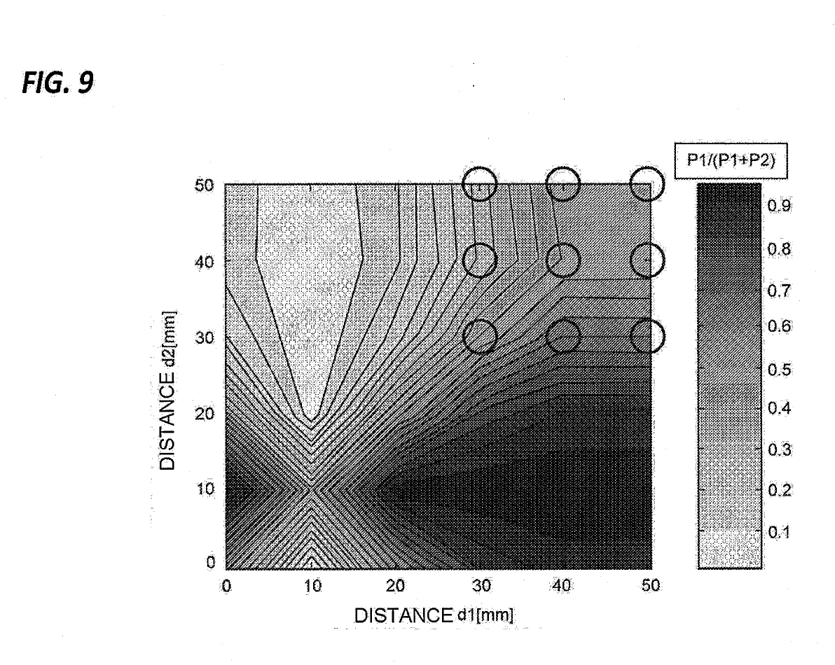

Further, the electric field strengths of the plasma processing apparatus 100 were calculated by simulation using the same settings as those of Test Example 1 and Test Example 2. In the simulation, the distance d1 and the distance d2 were set as parameters and varied, and an electric field strength P1 in the rod SP1 and an electric field strength P2 in the rod SP2 were calculated to obtain P1/(P1+P2) as a ratio of the electric field strengths. The result is illustrated in FIG. 9. In FIG. 9, the horizontal axis indicates a setting value of the distance d1, and the vertical axis indicates a setting value of the distance d2. FIG. 9 illustrates the ratio of the electric field strengths P1/(P1+P2) obtained by performing the calculation under the setting values of the distance d1 and the distance d2 in corresponding with the setting values of the distance d1 and the distance d2. Further, in FIG. 9, the ratios of the electric field strengths P1/(P1+P2) obtained under the same setting values as the setting values of the distance d1 and the distance d2 of Test Examples 1 and 2 are surrounded by circles. As a result of the simulation, it has been found that the ratios of electric field strength P1/(P1+P2) of the portions surrounded by the circles are matched with the light emitting state of plasma in Test Examples 1 and 2. Further, as illustrated in FIG. 9, it has also been found from the result of the simulation that, when the distances of the reflection plates of the plungers from the wave guiding paths are adjusted, the density distribution of plasma concentrated in the vicinity of a plurality of members made of a dielectric material may be adjusted.

As described above, various exemplary embodiments have been described, but various modifications may also be made without being limited to the above-mentioned exemplary embodiments. For example, in the above-mentioned exemplary embodiment, the plurality of protrusions made of a dielectric material is arranged along two concentric circles, that is, the first circle CC1 and the second circle CC2. However, the plurality of protrusions may be provided along three or more concentric circles.

### DESCRIPTION OF SYMBOL

10: plasma processing apparatus, 12: processing container, 14: antenna, 28: microwave generator, 36: cooling jacket, 40: metal plate, 40h: opening, 40i: gas injection port, 42: protrusion, 44: plunger, 44a: reflection plate, 44b: positioning mechanism, CC1: first circle, CC2: second circle, HT: heater, WG: wave guiding path, Z: axis, 14A: antenna, 40A: metal plate, 40Ah: opening, 42A: protrusion

1. A plasma processing apparatus, comprising:
a processing container that defines a processing space;
an antenna provided above the processing space and including a disc-shaped wave guiding path around a predetermined axis and a metal plate defining the wave guiding path from a lower side;
a microwave generator connected to the antenna and configured to generate microwaves;
a stage provided in the processing container and facing the antenna across the processing space to intersect with the predetermined axis; and
a heater configured to heat the metal plate,
wherein the metal plate includes a plurality of openings along a first circle around the predetermined axis and a second circle having a diameter larger than the first circle around the predetermined axis,
the antenna includes a plurality of protrusions made of a dielectric material extending out into the processing space through the plurality of openings, and
the microwaves are introduced around the predetermined axis.

2. The plasma processing apparatus of claim 1, further comprising:
plungers including reflection plates that face, among the plurality of protrusions, protrusions that pass through the openings formed along at least one of the first circle and the second circle through the wave guiding path, the plungers being capable of adjusting distances of the reflection plates from the wave guiding path in a direction in which the predetermined axis extends.

3. The plasma processing apparatus of claim 1, wherein the metal plate includes a plurality of gas injection ports to supply a processing gas to the processing space.

4. The plasma processing apparatus of claim 1, wherein the plurality of gas injection ports is formed along at least two concentric circles around the predetermined axis.

5. The plasma processing apparatus of claim 1, further comprising:
a cooling jacket provided on the wave guiding path.

6. The plasma processing apparatus of claim 1, wherein the plurality of protrusions is made of a rod-like dielectric material extending in a direction in which the predetermined axis extends, and the plurality of protrusions is arranged axisymmetrically with respect to the predetermined axis in the first circle and the second circle.

7. The plasma processing apparatus of claim 1, wherein the plurality of protrusions has an arc shape in a cross-section orthogonal to the predetermined axis, and the plurality of protrusions is arranged axisymmetrically with respect to the predetermined axis in the first circle and the second circle.
